(19) United States
(12) Patent Application Publication
(10) Pub. No.: US 2025/0335756 A1
(43) Pub. Date: Oct. 30, 2025

(54) DEEP NEURAL NETWORK ACCELERATOR AND ELECTRONIC DEVICE INCLUDING THE SAME

(71) Applicants: Jae Hoon KIM, Seoul (KR); Jin Soak KIM, Seoul (KR); Hyun-Ji SONG, Anyang-si (KR)

(72) Inventors: Jae Hoon KIM, Seoul (KR); Jin Soak KIM, Seoul (KR)

(73) Assignee: Hyun-Ji SONG, Anyang-si (KR)

(21) Appl. No.: 19/013,409

(22) Filed: Jan. 8, 2025

(30) Foreign Application Priority Data
Apr. 30, 2024 (KR) 10-2024-0058159

(51) Int. Cl. G06N 3/065; G11C 11/54

(52) U.S. Cl. CPC G06N 3/065; G11C 11/54

(57) ABSTRACT

Disclosed are a deep neural network accelerator and an electronic device including the same. The deep neural network accelerator may include a memory cell array including memory cells arranged along word lines and bit lines, wherein at least one of the memory cells includes a first transistor programmed such that a threshold voltage thereof is shifted by a shift voltage corresponding to a weight value; a row driver configured to apply a word line voltage corresponding to an input activation value to the word lines corresponding to the first transistor; and a column driver configured to measure a voltage drop caused by memory cells corresponding to a first bit line among the bit lines, wherein a gate-source voltage of the first transistor may be a voltage of a sub-threshold region.

### CROSS-REFERENCE TO RELATED APPLICATION

This application claims priority to and the benefit of Korean Patent Application No. 10-2024-0058159, filed on Apr. 30, 2024, the present disclosure of which is incorporated herein by reference in its entirety.

### BACKGROUND

### 1. Field of the Disclosure

The disclosure relates to a deep neural network accelerator and an electronic device including the same, and more particularly, to a deep neural network accelerator performing a matrix computation of a deep neural network using a memory cell array structure, an operating method of the deep neural network accelerator, and an electronic device including the deep neural network accelerator.

### 2. Description of the Related Art

Artificial intelligence technology has developed very rapidly due to the influence of high-performance computing systems and constantly growing open source data sets. In addition, artificial intelligence technology is being used in many application fields such as computer vision, language modeling, and autonomous driving as accuracy thereof improves.

However, the amount of calculation required for the computation of the deep neural network among artificial intelligence technologies is very large. Thus, when training is performed on the CPU, it takes a lot of time. GPU is good at parallel processing, so that it consumes less time than CPU. However, GPU has a low utilization rate due to the characteristics of the structure thereof. Recently, in order to overcome the disadvantages of CPU and GPU, many dedicated hardware accelerators for performing computations of deep neural networks have been proposed.

### SUMMARY

A purpose of the present disclosure is to provide a deep neural network accelerator having a structure of a memory cell array including memory cells, each composed of a transistor having a charge storage layer, and an electronic device including the same.

In an embodiment of the present disclosure, a deep neural network accelerator may be provided. The deep neural network accelerator may include a memory cell array including memory cells arranged along word lines and bit lines, wherein at least one of the memory cells is includes a first transistor programmed such that a threshold voltage thereof is shifted by a shift voltage corresponding to a weight value; a row driver configured to apply a word line voltage corresponding to an input activation value to the word lines corresponding to the first transistor; and a column driver configured to measure a voltage drop caused by memory cells corresponding to a first bit line among the bit lines, wherein a gate-source voltage of the first transistor is a voltage of a sub-threshold region.

In an embodiment of the present disclosure, a method for operating a deep neural network accelerator that performs a deep neural network computation may be provided. The method may include applying a word line voltage corresponding to an input activation value to at least one of word lines of a memory cell array; measuring a voltage drop corresponding to a pre-selected bit line among bit lines of the memory cell array; and obtaining a summed resistance value of transistors connected to the pre-selected bit line based on the measured voltage drop, wherein at least one of the transistors is programmed such that a threshold voltage thereof is shifted by a shift voltage corresponding to a weight value, wherein a gate-source voltage of each of the programmed at least one transistor is a voltage of a sub-threshold region.

In an embodiment of the present disclosure, an electronic device may be provided. The electronic device may include a deep neural network accelerator configured to perform a matrix computation of a deep neural network; a memory configured to store therein at least partial data of the deep neural network; and a processor configured to control the deep neural network accelerator and the memory. The deep neural network accelerator may include: a memory cell array including memory cells arranged along word lines and bit lines, wherein at least one of the memory cells includes a first transistor programmed such that a threshold voltage thereof is shifted by a shift voltage corresponding to a weight value of the deep neural network; a row driver configured to apply a word line voltage corresponding to an input activation value of the deep neural network to the word lines corresponding to the first transistor; and a column driver configured to measure a voltage drop caused by memory cells corresponding to a first bit line among the bit lines, wherein a gate-source voltage of the first transistor is a voltage of a sub-threshold region.

According to an embodiment of the present disclosure, the matrix computation of the deep neural network is implemented using the memory cell array structure, such that an area and cost-effective deep neural network accelerator may be provided.

### BRIEF DESCRIPTION OF THE DRAWINGS

The present disclosure may be easily understood based on the combination of the following detailed descriptions and the accompanying drawings, wherein reference numbers refer to structural elements.

FIG. 1 is a block diagram illustrating a configuration of a deep neural network accelerator according to an embodiment of the present disclosure.

FIG. 2 is a conceptual diagram showing a matrix computation of a deep neural network according to an embodiment of the present disclosure.

FIG. 3 is a circuit diagram illustrating a memory cell array according to an embodiment of the present disclosure.

FIG. 4 is a flowchart illustrating a configuration and a computation of a memory cell according to an embodiment of the present disclosure.

FIG. 5 is a conceptual diagram illustrating a method of measuring voltage drop or summed resistance corresponding to a matrix computation result of a deep neural network according to an embodiment of the present disclosure.

FIG. 6 is a graph showing a sub-threshold region of a transistor according to an embodiment of the present disclosure.

FIG. 7 is a graph showing a width of a sub-threshold region based on whether a transistor has a trap according to an embodiment of the present disclosure.

FIG. 8 is a circuit diagram illustrating a memory cell array according to an embodiment of the present disclosure.

FIG. 9 is a circuit diagram illustrating a computation of a memory cell array according to an embodiment of the present disclosure.

FIG. 10 is a block diagram illustrating a configuration of an electronic device according to an embodiment of the present disclosure.

FIG. 11 is a flowchart illustrating a method for operating a deep neural network accelerator according to an embodiment of the present disclosure.

### DETAILED DESCRIPTION

Although the terms used herein are selected from among common terms that are currently widely used in consideration of their functions in the present disclosure, the terms may vary according the intention of one of ordinary skill in the art, a precedent, or the advent of new technology. Further, in particular cases, the terms are discretionally selected by the applicant of the present disclosure, and the meaning of those terms will be described in detail in the corresponding part of the detailed description. Therefore, the terms used in the present disclosure are not merely designations of the terms, but the terms are defined based on the meaning of the terms and content throughout the present disclosure.

As used herein, the singular forms “a,” “an,” and “the” are intended to include the plural forms as well, unless the context clearly indicates otherwise. The terms including technical and scientific terms used herein have the same meaning as commonly understood by one of ordinary skill in the art to which the present disclosure belongs.

Throughout the present application, when a part “includes” an element, it is to be understood that the part additionally includes other elements rather than excluding other elements as long as there is no particular opposing recitation. Further, the terms such as “ . . . unit,” “module,” or the like used in the present disclosure indicate a unit, which processes at least one function or motion, and the unit may be embodied as hardware or software, or a combination of hardware and software.

The expression “configured to (or set to)” used herein may be replaced with, for example, “suitable for,” “having the capacity to,” “designed to,” “adapted to,” “made to,” or “capable of” according to cases. The expression “configured to (or set to)” may not necessarily mean “specifically designed to” in hardware. Instead, in some cases, the expression “system configured to . . . ” may mean that the system is “capable of . . . ” along with other devices or parts. For example, “a processor configured to (or set to) perform A, B, and C” may refer to a dedicated processor (e.g., an embedded processor) for performing a corresponding operation, or a general-purpose processor (e.g., a central processing unit (CPU) or an application processor (AP)) capable of performing a corresponding operation by executing one or more software programs stored in a memory.

In addition, in the present disclosure, when one component is referred to as “connected” or “coupled” to another component, it should be understood that one component may be directly connected or directly coupled to another component, or one component may be connected or coupled to another component via still another component interposed therebetween unless there is a particularly opposite description.

In the present disclosure, functions related to an artificial intelligence (AI) or a deep neural network (DNN) according to embodiments of the present disclosure may operate via a processor and a memory. The processor may be configured as one or a plurality of processors. In this case, the one or plurality of processors may be a general-purpose processor, such as a central processing unit (CPU), an application processor (AP), or a digital signal processor (DSP), a dedicated graphics processor, such as a graphics processing unit (GPU) or a vision processing unit (VPU), or a dedicated AI or DNN processor, such as a neural processing unit (NPU). The one or plurality of processors may control input data to be processed according to predefined operation rules or an AI or DNN model stored in the memory. Alternatively, when the one or more processors are a dedicated AI or DNN processor, the dedicated AI or DNN processor may be designed with a hardware structure specialized for processing a particular AI or DNN model.

The predefined operation rules or AI or DNN model may be created via a training process. The creation via the training process means that the predefined operation rules or AI or DNN model set to perform desired characteristics (or purpose) are created by training a basic AI or DNN model based on a large number of training data via a learning algorithm. The training process may be performed by an apparatus itself in which AI or DNN is performed or via a separate server and/or system. Examples of the learning algorithm may include, but are not limited to, supervised learning, unsupervised learning, semi-supervised learning, and reinforcement learning.

In the present disclosure, the AI model or the DNN model may include a plurality of neural network layers. Each of the plurality of neural network layers has a plurality of weight values and may perform neural network computations via calculations between a result of computations in a previous layer and a plurality of weight values. A plurality of weight values assigned to each of the plurality of neural network layers may be optimized based on a result of training the AI or DNN model. For example, a plurality of weight values may be modified to reduce or minimize a loss or cost value obtained in the AI or DNN model during a training process. The deep neural network (DNN) may be, for example, a convolutional neural network (CNN), a DNN, a recurrent neural network (RNN), a restricted Boltzmann machine (RBM), a deep belief network (DBN), a bidirectional recurrent DNN (BRDNN), or deep Q-networks (DQN), but is not limited thereto.

Hereinafter, embodiments of the present disclosure will be described in detail with reference to the accompanying drawings so that those skilled in the art to which the present disclosure pertains can easily implement the embodiments. However, the present disclosure may be implemented in various different forms and is not limited to the embodiments described herein.

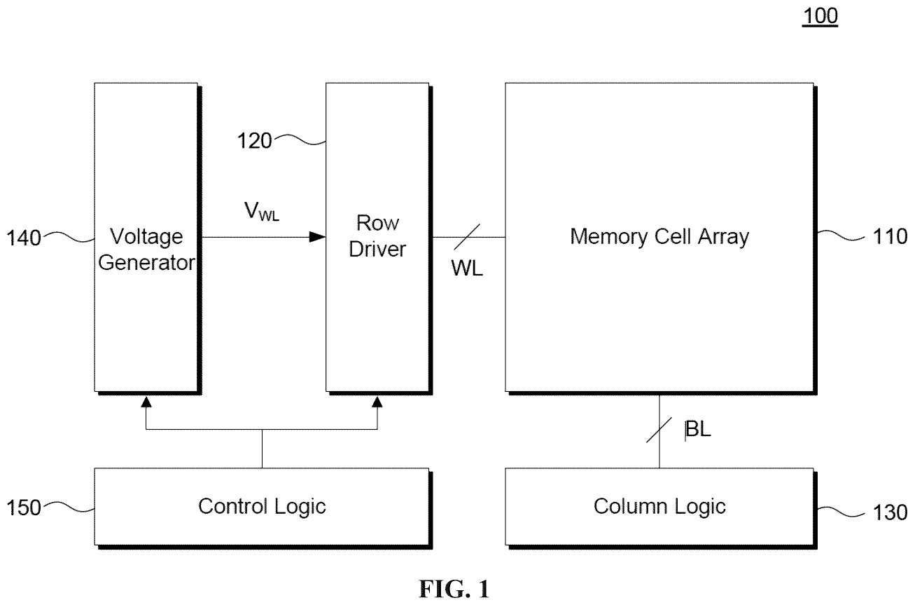

FIG. 1 is a block diagram illustrating a configuration of a deep neural network accelerator according to an embodiment of the present disclosure.

Referring to FIG. 1, the deep neural network accelerator 100 may include a memory cell array 110, a row driver 120, a column driver 130, a voltage generator 140, and a control logic 150. However, not all of the components shown are essential components. The deep neural network accelerator 100 may be implemented by a configuration in which further components are added to the illustrated components, or the deep neural network accelerator 100 may be implemented by a configuration in which fewer components are omitted from the illustrated components.

The memory cell array 110 may include a plurality of memory cells MC arranged along word lines w_{L} and bit lines BL. A gate terminal of each of the plurality of memory cells may be connected to a corresponding word line, and a drain terminal and a source terminal may be connected to a corresponding bit line. The plurality of memory cells MC may be arranged in the memory cell array 110 in a form in which the word line w_{L} and the bit line BL intersect each other. For example, the memory cell array 110 may have a structure of a memory cell array of a NAND flash memory device. In this case, the memory cell array 110 may include NAND flash memory cells. However, the present disclosure is not limited thereto, and the memory cell array 110 may have any array structure including programmable memory cells arranged along word lines and bit lines.

Each of the memory cells of the memory cell array 110 may include a programmable area. In the present disclosure, a programmable area may represent an area in which charges may be accumulated (or stored). The memory cell MC may be embodied as a memory cell having a charge storage layer such as a floating gate and/or a charge trap layer, a memory cell having a variable resistor element, or the like. However, the present disclosure is not limited thereto.

In an embodiment of the present disclosure, the memory cell MC may store therein analog data corresponding to a weight value. However, the present disclosure is not limited thereto. For example, the memory cell may store therein 1-bit data or multi-bit data corresponding to the weight value.

In an embodiment of the present disclosure, the memory cell array 110 may be implemented to have a single-layer array structure (or may also be referred to as a two-dimensional array structure) or a multi-layer array structure (or may also be referred to as a three-dimensional array structure). However, the present disclosure is not limited thereto.

At least one of the memory cells of the memory cell array 110 may store therein data corresponding to a weight value of the deep neural network model. In an embodiment of the present disclosure, the memory cell MC may include a transistor. At least one of the memory cells may include a transistor programmed such that a threshold voltage thereof is shifted by a shift voltage corresponding to a weight value of the deep neural network model. As the charge corresponding to the weight value is stored in the charge storage layer of the memory cell MC, an existing threshold voltage (hereinafter, a first threshold voltage) of the transistor may be shifted. The shift voltage may represent a difference between the existing threshold voltage and a threshold voltage (hereinafter, a second threshold voltage) having shifted by the shift voltage from the existing threshold voltage.

The row driver 120 may perform a selection and/or driving operation on rows of the memory cell array 110. The voltage generator 140 may be controlled by the control logic 150 and may generate a word line voltage V_{WL} corresponding to an input activation value. The row driver 120 may apply the word line voltage V_{WL} to a word line corresponding to the selected row (or a selected transistor). In the present disclosure, the word line voltage V_{WL} may represent a voltage obtained by summing a voltage corresponding to the input activation value and a reference voltage.

In an embodiment of the present disclosure, the voltage generator 140 may generate an erase voltage and/or a write voltage to store a charge corresponding to a weight value in a transistor of a memory cell. The row driver 120 may apply an erase voltage and/or a write voltage to the word line to erase the charge stored in the memory cell MC and/or store the charge corresponding to a new weight value.

The column driver 130 may be controlled by the control logic 150. The column driver 130 may operate as a voltage measurer or a write driver according to an operation mode. For example, in a matrix computation mode, the column driver 130 may operate as a voltage measurer that measures a voltage drop by memory cells corresponding to a selected bit line (e.g., a first bit line) among the bit lines. For example, in the write mode, the column driver 130 may operate as a write driver that drives memory cells of a selected row based on a weight value. The column driver 130 may sequentially select the columns on a predetermined unit basis. Although not shown, the deep neural network accelerator 100 may further include an input/output interface. The input/output interface may be configured to communicate with an external device. For example, the input/output interface may transmit the measured voltage drop to the external device.

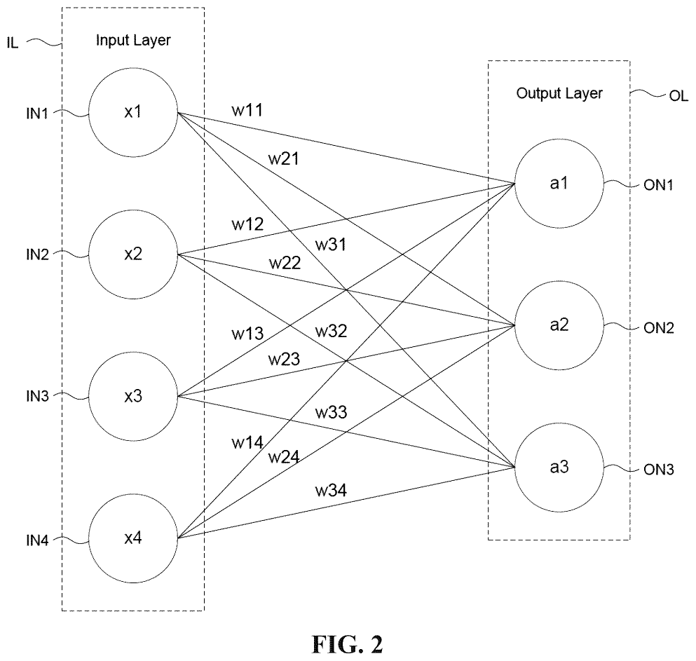

FIG. 2 is a conceptual diagram showing a matrix computation of a deep neural network according to an embodiment of the present disclosure. For convenience of description, contents duplicate the contents as described above with reference to FIG. 1 may be omitted.

Referring to FIG. 2, the deep neural network model is illustrated as including an input layer IL and an output layer OL. However, the present disclosure is not limited thereto. For example, the deep neural network model may include a plurality of layers, and in this case, the input layer IL may act as an output layer of another layer, and the output layer OL may act as an input layer of another layer. For example, the input layer IL and the output layer OL may be interpreted as hidden layers.

For convenience of description, the input layer IL includes four nodes IN1, IN2, IN3, and IN4, and the output layer OL includes three nodes ON1, ON2, and ON3. However, the present disclosure is not limited to the number of nodes of the input layer IL and the output layer OL.

Although the input layer IL and the output layer OL are illustrated as being fully-connected layers for convenience of description, the present disclosure is not limited thereto. At least one node of the input layer IL and at least one node of the output layer OL may not be connected according to the structure of the deep neural network.

Each of the input nodes IN1, IN2, IN3, and IN4 of the input layer IL may correspond to each of the input activation values x1, x2, x3, and x4. Each of the output nodes ON1, ON2, and ON3 may correspond to each of the output values a1, a2, and a3.

The connections from the input nodes IN1, IN2, IN3, and IN4 to the output nodes ON1, ON2, and ON3 may be expressed as weight values w11, w12, w13, w14, w21, w22, w23, w24, w31, w32, w33, and w34. For example, a weight value from the first input node IN1 to the first output node ON1 may be expressed as w11, a weight value from the first input node IN1 to the second output node ON2 may be expressed as w21, and a weight value from the first input node IN1 to the third output node ON3 may be expressed as w31.

$$[ Equation 1 ]$$

$$( \begin{matrix}w 11 & w 12 w 13 & w 14 \\ w 21 & w 22 w 23 & w 24 \\ w 31 & w 32 w 33 & w 34\end{matrix} ) ( \begin{matrix}x 1 \\ x 2 \\ x 3 \\ x 4\end{matrix} ) + ( \begin{matrix}b 1 \\ b 2 \\ b 3\end{matrix} ) = ( \begin{matrix}w 11 * x 1 + w 12 * x 2 + w 13 * x 3 + w 14 * x 4 + b 1 \\ w 21 * x 1 + w 22 * x 2 + w 23 * x 3 + w 24 * x 4 + b 2 \\ w 31 * x 1 + w 32 * x 2 + w 33 * x 3 + w 34 * x 4 + b 3\end{matrix} ) = ( \begin{matrix}a 1 \\ a 2 \\ a 3\end{matrix} )$$

Referring to the Equation 1, when the deep neural network is calculated using the matrix computation, the input layer may be represented by one input vector x1, x2, x3, and x4, and the weight values may be represented by a 3×4 matrix. In an embodiment of the present disclosure, a bias value may be added to a matrix multiplication result value between a vector of the input layer and a weight matrix. However, the present disclosure is not limited thereto, and the bias value may be omitted. The result of the matrix computation may be represented by one output vector a1, a2, and a3 corresponding to the output layer OL. The output vector a1, a2, and a3 may represent the result value of the matrix computation as in Equation 1. However, the present disclosure is not limited thereto. For example, the output vector a1, a2, and a3 may represent a value obtained by applying an activation function to the result value of the matrix computation according to Equation 1.

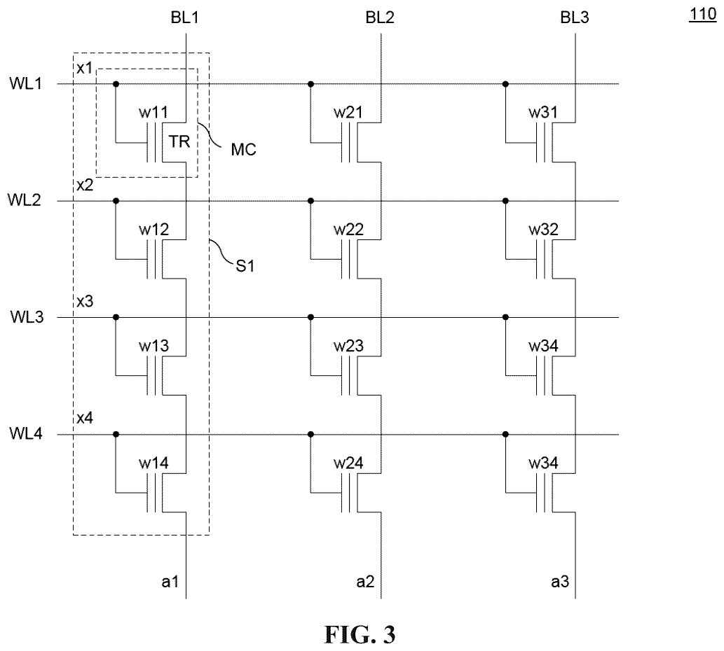

FIG. 3 is a circuit diagram illustrating a memory cell array according to an embodiment of the present disclosure. For convenience of description, contents duplicate the contents as described above with reference to FIGS. 1 and 2 may be omitted.

Although FIG. 3 illustrates that the memory cell array 110 includes 12 memory cells MC arranged along four word lines WL1, WL2, WL3, and WL4 and three bit lines BL1, BL2, and BL3, the present disclosure is not limited thereto. The memory cell array 110 may include any number of word lines, any number of bit lines, and any number of memory cells.

Referring to FIG. 2 together with FIG. 3, a word line voltage corresponding to the first input activation value x1 may be applied to the first word line WL1. A word line voltage corresponding to the second input activation value x2 may be applied to the second word line WL2. A word line voltage corresponding to the third input activation value x3 may be applied to the third word line WL3. A word line voltage corresponding to the fourth input activation value x4 may be applied to the fourth word line WL4.

Each of the memory cells MC of the memory cell array 110 may include a transistor TR. The transistor TR may store therein a charge corresponding to a weight value. For example, each of the respective transistors of the memory cells of a first string S1 corresponding to the first bit line BL1 may store therein each of charges corresponding to each of the weight values w11, w12, w13, and w14 between the first output node ON1 and each of the input nodes IN1, IN2, IN3, and IN4. For example, a transistor connected to the first word line WL1 may store therein a charge corresponding to the weight value w11. For example, a transistor connected to the second word line WL2 may store therein a charge corresponding to the weight value w12. For example, a transistor connected to the third word line WL3 may store therein a charge corresponding to the weight value w13.

For example, a transistor connected to the fourth word line WL4 may store therein a charge corresponding to the weight value w14.

In an embodiment of the present disclosure, when a voltage corresponding to an input activation value is applied to a word line, and charge corresponding to the weight value is stored in a corresponding transistor, a voltage drop between a drain and a source of the transistor may correspond to a multiplication value between the input activation value and the weight value. One string may correspond to one node of the output layer OL The voltage drop by transistors of a particular string may correspond to a result value of a matrix computation corresponding to one of the output nodes. For example, the voltage drop by the transistors of the first string S1 may correspond to the computation result value a1 of the first output node ON1.

In an embodiment of the present disclosure, a constant voltage or current may be supplied (or applied) to the bit lines. The voltage or current supplied to the bit lines BL may be predetermined to a level that maximizes a width of the sub-threshold region. However, the present disclosure is not limited thereto, and the voltage or current supplied to the bit lines BL may vary based on the setting of the manufacturer. A current of a specific level may flow through each of the bit lines BL under the voltage or current supplied to the bit lines BL. According to Ohm's law, the voltage drop between the drain and the source of the transistor may be proportional to the resistance value resulting from the transistor. Accordingly, a resistance value by transistors of a specific string may correspond to a computation result value corresponding to one of the output nodes. For example, the sum of the resistance values by the transistors of the first string S1 may correspond to the computation result value a1 of the first output node ON1.

In an embodiment of the present disclosure, the matrix computation performed by the memory cell array 110 may correspond to an inference computation of the deep neural network model. Accordingly, the charge stored in each of the transistors may not be updated. However, the present disclosure is not limited thereto, and the charge value stored in the transistor may be updated through an additional erase and/or program operation according to a manufacturer or a user's setting.

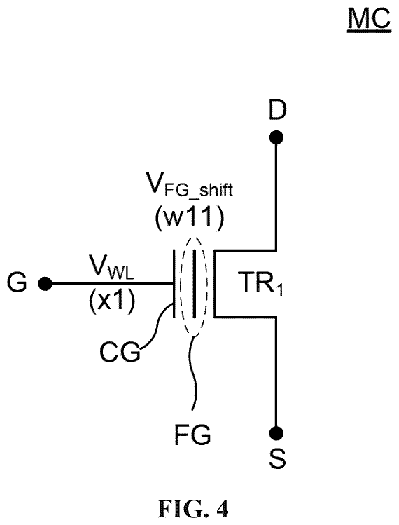

FIG. 4 is a flowchart illustrating a configuration and an operation of a memory cell according to an embodiment of the present disclosure. For convenience of description, contents duplicate with those as described above with reference to FIGS. 1 to 3 will be omitted. Hereinafter, in order to describe an operation of each of the memory cells MC of the memory cell array 110 of FIG. 3, a memory cell MC connected to a first word line WL1 and a first bit line BL1 among the memory cells MC is illustrated by way of example.

Referring to FIG. 3 together with FIG. 4, the memory cell MC may include a transistor TR₁. The transistor TR₁ may be a transistor including a charge storage layer. In FIG. 4, the transistor TR₁ is illustrated as a transistor including a floating gate. However, the present disclosure is not limited thereto.

The transistor TR₁ may receive the word line voltage V_{WL} corresponding to the input activation value x1 through a first terminal (e.g., a gate terminal) G. The first terminal G of the transistor TR₁ may include a control gate CG and a floating gate FG. The charge corresponding to the weight value w11 may be stored in the floating gate FG of the transistor TR₁. The charge corresponding to the weight value w11 may be pre-stored in the transistor TR₁ through a program operation. A threshold voltage of the transistor TR₁ may be shifted by a shift voltage V_{FG_shift} due to the charge stored in the floating gate FG.

$${V}_{G} = {V}_{WL} + {V}_{FG \_ shift} \qquad [ Equation 2 ]$$

Referring to Equation 2, a gate voltage V_{G} applied to the transistor TR₁ through the first terminal G may be evaluated as a voltage level obtained by summing the word line voltage V_{WL} and the shift voltage V_{FG_shift}.

A constant current may flow between a second terminal (e.g., a drain terminal) D and a third terminal (e.g., a source terminal) S of the transistor TR₁. As the gate voltage VG is applied through the first terminal G of the transistor TR₁, the transistor TR₁ may operate as a resistor that interferes with the current flowing between the second terminal D and the third terminal S. Accordingly, the voltage drop may occur between the second terminal D and the third terminal S of the transistor TR₁.

In an embodiment of the present disclosure, the resistance or the voltage drop by the transistor TR₁ may correspond to a result of multiplication between the input activation value x1 and the weight value w11.

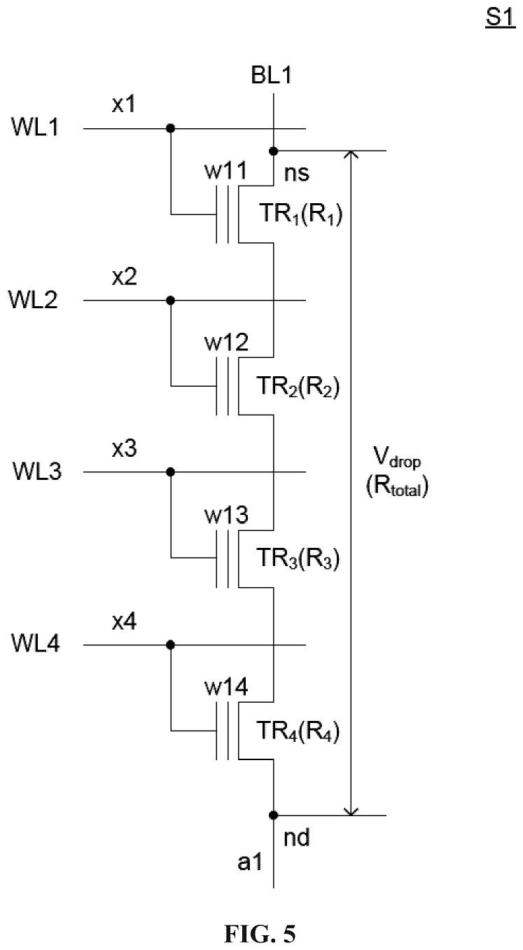

FIG. 5 is a conceptual diagram illustrating a method of measuring a voltage drop or a summed resistance corresponding to a matrix computation result of a deep neural network according to an embodiment of the present disclosure. For convenience of description, contents duplicate with those described above with reference to FIGS. 1 to 4 will be omitted. Hereinafter, an example in which the voltage drop or the summed resistance is measured on a first string S1 basis in the memory cell array 110 of FIG. 3 is described.

Referring to FIGS. 3 and 4 together with FIG. 5, the first string S1 may include a plurality of memory cells MC. For example, a first memory cell may include a transistor TR₁. The transistor TR₁ may operate as a resistor having a first resistance value R₁, which interferes with a current flowing through the first bit line BL1. For example, a second memory cell may include a transistor TR₂. The transistor TR₂ may operate as a resistor having a second resistance value R₂ that interferes with a current flowing through the first bit line BL1. For example, a third memory cell may include a transistor TR₃. The transistor TR₃ may operate as a resistor having a third resistance value R₃ that interferes with a current flowing through the first bit line BL1. For example, a fourth memory cell may include a transistor TR₄. The transistor TR₄ may operate as a resistor having a fourth resistance value R₄ that interferes with a current flowing through the first bit line BL1.

In an embodiment of the present disclosure, the column driver 130 of FIG. 1 may measure a voltage drop V_{drop} by the memory cells between a start node ns and an end node nd of the first bit line BL1. Since a specific current is generated in the first bit line BL1 under application of a voltage or a current, the column driver 130 of FIG. 1 may measure a total resistance value Rₜₒₜₐₗ of the first bit line BL1 based on the measured voltage drop. For convenience of description, the total resistance value Rₜₒₜₐₗ is expressed as a sum value of the first to fourth resistance values R₁, R₂, R₃, and R₄. Alternatively, the total resistance value Rₜₒₜₐₗ may be a value obtained by subtracting a line resistance in the bit line BL1 from the sum value of the first to fourth resistance values R₁, R₂, R₃, and R₄.

In an embodiment of the present disclosure, the voltage drop or the summed resistance of each of the strings corresponding to the bit lines of the memory cell array 110 may correspond to one node of the output layer. For example, the voltage drop or summed resistance of each of the strings may correspond to a cumulative summation value of multiplication values between the input activation value and the weight value. For example, the voltage drop or summed resistance of the first string S1 may correspond to a value a1 obtained by cumulatively summing the multiplication values x1*w11, x2*w12, x3*w13, and x4*x14 between the four input activation values and the four weight values.

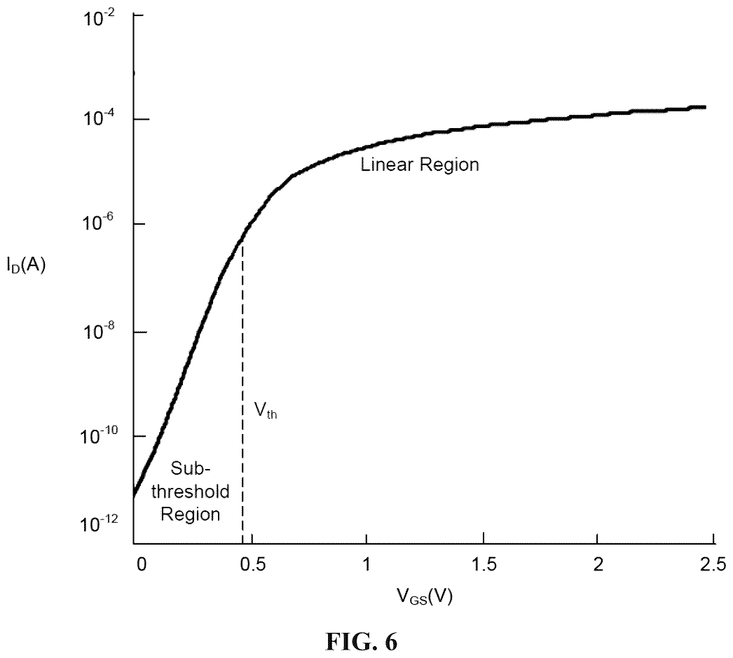

FIG. 6 is a graph showing a sub-threshold region of a transistor according to an embodiment of the present disclosure. For convenience of description, contents duplicate with those described above with reference to FIGS. 1 to 5 will be omitted.

Referring to FIGS. 3 to 5 together with FIG. 6, a voltage level that is comprehensively applied to the first terminal G of a transistor (e.g., the first transistor TR₁) may be referred to as a gate voltage V_{G}. A difference between a voltage of the first terminal G and a voltage of the third terminal S of a transistor (e.g., the first transistor TR₁) may be referred to as a gate-source voltage V_{GS}. A region of a voltage level of the gate-source voltage V_{GS} may be divided into a sub-threshold region and a linear region based on a threshold voltage Vₜₕ as a boundary. A current flowing through a channel formed between the second terminal D and the third terminal S of a transistor (e.g., the first transistor TR₁) may be referred to as a drain current I_{D}.

In the sub-threshold region STH, the drain current I_{D} flowing through the channel of the transistor may be exponentially proportional to the gate voltage V_{G}. That is, the drain current I_{D} in the sub threshold region STH may increase exponentially as the gate voltage V_{G} increases. The relationship between the drain current I_{D} and the gate voltage V_{G} in the sub-threshold region may be established as Equation 3 as approximation according to the Taylor series.

$${I}_{D} ( {V}_{G} ) = exp ( {V}_{WL} + {V}_{FG \_ shift} ) = exp ( {V}_{WL} ) * exp ( {V}_{FG \_ shift} ) \qquad [ Equation 3 ]$$

Since the current has an inverse relationship with the resistance, a resistance value that hinders the flow of the drain current I_{D} between the second terminal D and the third terminal S of the transistor TR may also be exponentially proportional to the gate voltage V_{G}.

According to Equation 3, a drain current and/or a drain-source resistance value of a transistor operating in the sub-threshold region STH may represent a multiplication value between the word line voltage V_{WL} and the shift voltage V_{FG_shift}. That is, the drain current and/or the drain-source resistance value of the transistor operating in the sub-threshold region STH may represent a multiplication value between the input activation value and the weight value.

Referring to FIG. 5, a resistance value corresponding to each of the transistors may correspond to a multiplication value between one input activation value and one weight value. The voltage drop V_{drop} or the summed resistance Rₜₒₜₐₗ by the transistors may correspond to a value obtained by cumulatively summing up the multiplication values corresponding to the transistors. According to an embodiment of the present disclosure, an area-efficient deep neural network accelerator may be provided by enabling artificial intelligence or deep neural network computation without an accumulator. In addition, since an operation of the accumulator is omitted, a deep neural network accelerator capable of performing a deep neural network computation with low latency may be provided.

The gate voltage V_{G} represents an absolute voltage applied to the first terminal G of the transistor TR, and is different from the gate-source voltage V_{GS} representing a voltage difference between the voltage of the first terminal G and the voltage of the third terminal S of the transistor. The gate-source voltage V_{GS} may have a level obtained by subtracting the word line voltage V_{WL} and the shift voltage V_{FG_shift} from the reference voltage. The reference voltage may have a voltage level greater than or equal to the threshold voltage V_{TH}. However, the present disclosure is not limited thereto. The gate-source voltage VGS may have a level obtained by applying, to the reference voltage, a value obtained by summing the word line voltage V_{WL} and the shift voltage V_{FG_shift} as a negative offset. As a result, the gate-source voltage VGS may have a voltage level of the sub-threshold region.

TABLE 1

| | | | V_{WL} | V_{FG}_{_{—}}_{shift} | V_{WL} + V_{FG}_{_{—}}_{shift} | | | |
|---|---|---|---|---|---|---|---|---|
| x | w | x*w | [In(x)/k] | [In(w)/k] | [{In(x) + In(w)}/k] | V_{ref} | V_{GS} | R |
| 12 | 5 | 60 | 0.0994 | 0.0644 | 0.1638 | 1.45 | 1.2862 | 348.559 |
| 10 | 6 | 60 | 0.0921 | 0.0717 | 0.1638 | 1.45 | 1.2862 | 348.559 |
| 12 | 6 | 72 | 0.0994 | 0.0717 | 0.1711 | 1.45 | 1.2789 | 356.071 |
| 14 | 6 | 84 | 0.1056 | 0.0717 | 0.1773 | 1.45 | 1.2728 | 362.487 |

Referring to Table 1, x may represent an input activation value, w may represent a weight value, V_{ref} may represent a level of a reference voltage, V_{GS} may represent a level of a gate-source voltage, R may represent a drain-source resistance value of a transistor, and k may be defined as an arbitrary variable. Hereinafter, it is assumed that the k is 25. However, the k value is not limited thereto and may vary depending on a manufacturer or a user's setting. The word line voltage V_{WL} may be defined as a value proportional to ln(x). The shift voltage V_{FG_shift} may defined as a value proportional to ln(w). For example, when x is 12 and w is 6, the word line voltage V_{WL} may be predefined as 0.0994V and the shift voltage V_{FG_shift} may be predefined as 0.0644V. 0.1638V which is a sum of the word line voltage V_{WL} and the shift voltage V_{FG_shift} may act as a negative offset which may be applied to the reference voltage V_{ref}. As a result, the gate-source voltage VGS may have a level of 1.2862V obtained by subtracting 0.1638V from the reference voltage V_{ref} 1.45V. As a result, the gate-source voltage VGS may have a voltage level of a sub-threshold region that is lower than or equal to the threshold voltage. In this case, the resistance value of the transistor may be 348.559Ω. Referring to Table 1, it may be identified that the multiplication result between the input activation value and the weight value is proportional to the resistance value of the transistor.

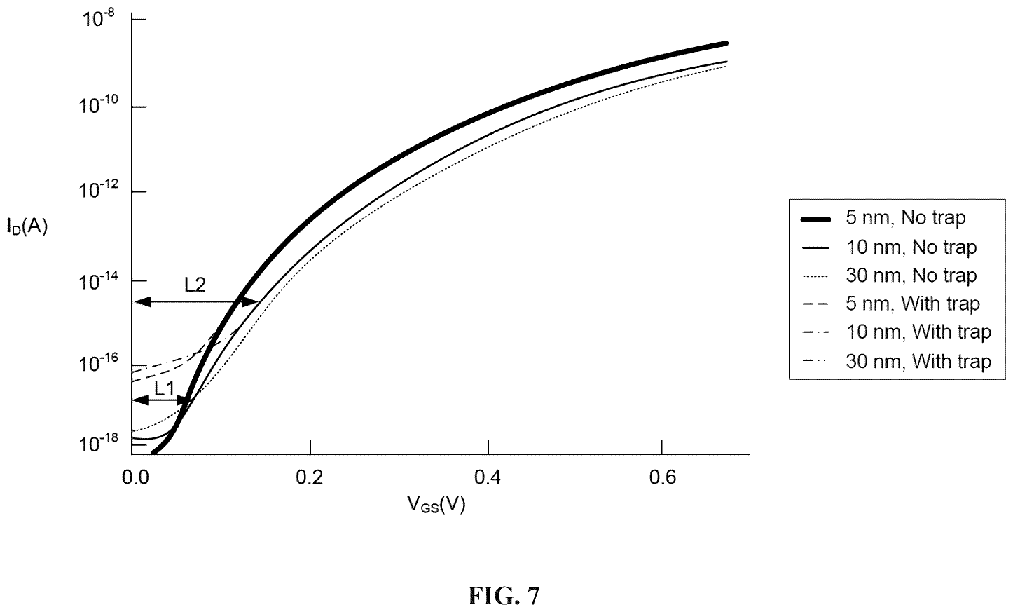

FIG. 7 is a graph showing a width of a sub-threshold region based on whether a transistor has a trap according to an embodiment of the present disclosure. For convenience of description, contents duplicate the contents as described above with reference to FIGS. 1 to 6 will be omitted. In the present disclosure, the trap may also be referred to as an impurity.

Referring to FIG. 7, it may be identified that the width of the sub-threshold region increases based on whether a channel forming area of a transistor of a memory cell has a trap. For example, it may be identified that a transistor having no trap has a sub-threshold region of a first width L1 on average, whereas a transistor having a trap has a sub-threshold region of a second width L2 on average. According to an embodiment of the present disclosure, the second width L2 may be larger than the first width L1.

In an embodiment of the present disclosure, the transistor may be manufactured through a process (e.g., a first process) of adding impurities to the channel forming area. According to an embodiment of the present disclosure, adding the impurities to the channel forming area may allow the voltage of the sub-threshold region to be utilized more variously, and thus, a deep neural network accelerator (100 of FIG. 1) for performing the matrix computation of various values (e.g., high precision and/or wide bit width) may be provided.

In an embodiment of the present disclosure, the transistor may be manufactured through a passivation process (e.g., a second process) of adjusting an interface impurity (a surface trap) between the channel forming area and a gate insulating film. In the present disclosure, the passivation process may represent a process of forming a protective layer between the channel forming area and the gate insulating film of the transistor. For example, the passivation process in the transistor manufacturing process may be performed as a passivation process that minimizes a thickness of the protective layer between the channel forming area and the gate insulating film. According to an embodiment of the present disclosure, since the thickness of the protective layer is minimized, impurities (which may also be referred to as interface impurities (surface trap)) may be generated at the interface between the channel forming area and the gate insulating film, and the sub-threshold region of the transistor may be widened due to the impurities.

In an embodiment of the present disclosure, the passivation process of adjusting the interface impurity (surface trap) between the channel forming area and the gate insulating film of the of transistor may be omitted. The transistor may be manufactured through a process (e.g., a third process) of omitting the process of forming the protective layer between the channel forming area and the gate insulating film. According to an embodiment of the present disclosure, since the protective layer formed by the passivation process is omitted, impurities (which may also be referred to as interface impurities (surface trap)) may be generated at the interface between the channel forming area and the gate insulating film, such that the sub-threshold region of the transistor may be widened due to the generated impurities.

In an embodiment of the present disclosure, the gate insulating film may include silicon oxide, silicon oxynitride, silicon nitride, or a high-k material having a dielectric constant greater than that of silicon oxide. The high-k material may include, for example, one of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, or combinations thereof. However, embodiments of the present disclosure are not limited thereto. According to an embodiment of the present disclosure, adding or omitting the passivation process of adjusting the protective layer may allow the voltage of the sub-threshold region to be utilized more variously, and thus, a deep neural network accelerator (100 of FIG. 1) for performing the matrix computation of various values (e.g., high precision and/or wide bit width) may be provided.

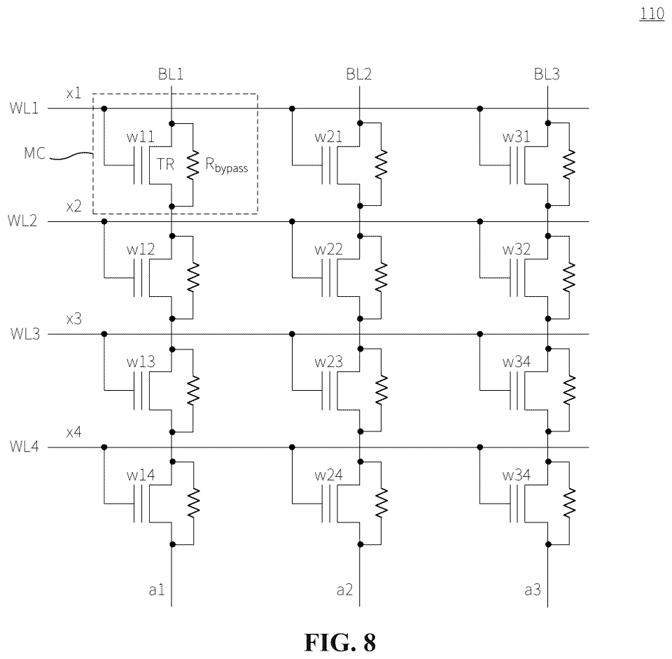

FIG. 8 is a circuit diagram illustrating a memory cell array according to an embodiment of the present disclosure. For convenience of description, contents duplicate the contents as described above with reference to FIGS. 1 to 7 will be omitted.

Referring to FIG. 8, unlike the memory cell MC illustrated in FIG. 2, the memory cell MC may include a transistor TR and a bypass resistor element R_{bypass}. Since the function, operation, and configuration of the transistor TR correspond to the function, operation, and configuration of the transistor TR of FIG. 2, redundant descriptions thereof will be omitted.

The bypass resistor R_{bypass} may be connected to and disposed between the drain terminal and the source terminal of the transistor TR. A sub-threshold slope of the sub-threshold region may be adjusted through a resistance value of the bypass resistor element R_{bypass}. In the present disclosure, the sub-threshold slope may refer to an index indicating how much the drain current increases when the gate voltage increases. As the resistance value of the bypass resistor element R_{bypass} increases, the magnitude of the drain current flowing through the transistor TR may increase. Based on these characteristics, the resistance value of the bypass resistor element R_{bypass} may be preset such that the width of the sub-threshold region and/or the slope of the exponential proportional section may be adjusted.

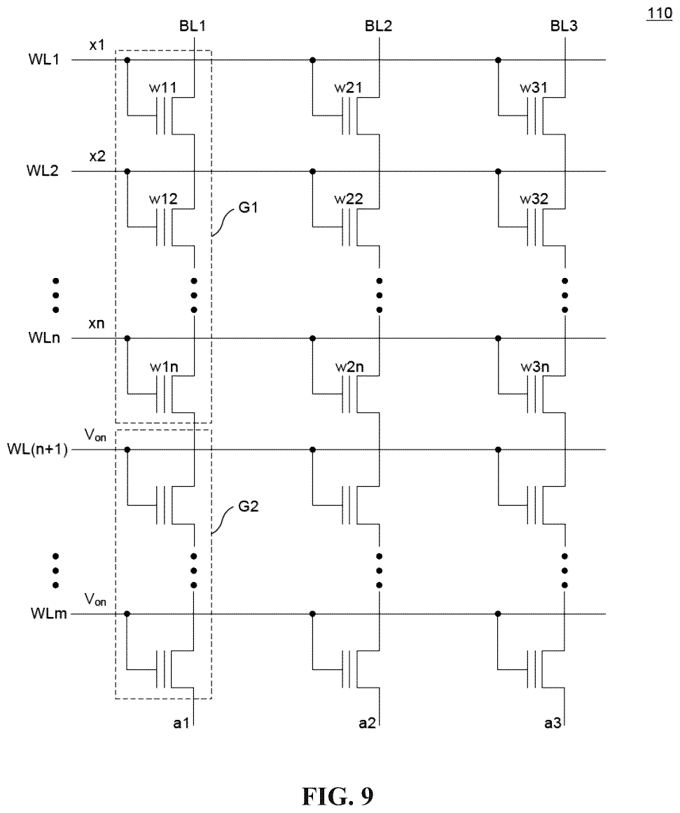

FIG. 9 is a circuit diagram illustrating a computation of a memory cell array according to an embodiment of the present disclosure. For convenience of description, contents duplicate with those described above with reference to FIGS. 1 to 8 will be omitted.

Referring to FIG. 9, the memory cell array 110 may include memory cells MC arranged along bit lines BL and word lines WL. At least one of the memory cells may include a first transistor programmed such that a threshold voltage thereof is shifted by a shift voltage corresponding to a weight value. At least one memory cell including the first transistor may be grouped into a first group G1. At least one of the memory cells may include a second transistor. The second transistor may not be involved in the deep neural network computation. At least one memory cell including the second transistor may be grouped into a second group G2. The gate-source voltage VGS resulting from the word line voltage V_{WL} applied to the second transistor may be an on-state voltage Vₒₙ equal to or greater than the threshold voltage.

The row driver (120 of FIG. 1) may respectively apply the word line voltages corresponding to the input activation values x1 to xn to the word lines WL1 to WLn corresponding to the first transistor. The row driver (120 of FIG. 1) may apply the on-state voltage Vₒₙ to the word lines WL(n+1) to WLm corresponding to the second transistor.

The total number of memory cells (or transistors) connected in series to the bit line (that is, the total number of memory cells belonging to one string) may be m. The total number of memory cells (or first transistors) of the first group G1 may be n. The total number of memory cells (or second transistors) of the second group G2 may be m-n. In this regard, n and m are natural numbers.

For example, m may be 100, and n may be 10. The 10 memory cells may perform a deep neural network computation, and the second transistors of the 90 memory cells may operate in a turned-on state. The column driver (130 of FIG. 1) may obtain the result of the deep neural network computation by measuring the voltage drop and/or the summed resistance of the 10 memory cells of the first group G1. According to an embodiment of the present disclosure, using only some memory cells in one string may disallow a malfunction of a sense amplifier of the column driver (130 in FIG. 1).

For convenience of description, the bypass resistor element R_{bypass} of FIG. 8 is omitted. However, in an embodiment of the present disclosure, the memory cell may further include the bypass resistor element.

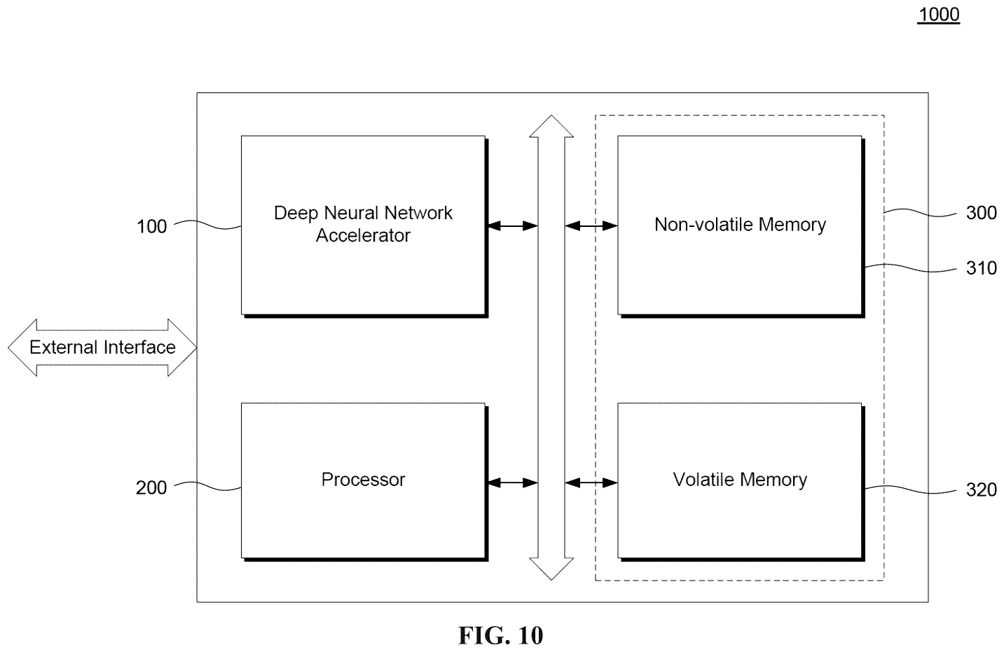

FIG. 10 is a block diagram illustrating a configuration of an electronic device according to an embodiment of the present disclosure. For convenience of description, contents duplicate the contents as described above with reference to FIGS. 1 to 9 will be omitted. The operation, function, and configuration of the deep neural network accelerator 100 may correspond to the operation, function, and configuration of the deep neural network accelerator 100 of FIG. 1.

Referring to FIG. 10, referring to FIG. 2, an electronic device 1000 may include the deep neural network accelerator 100, a processor 200, and a memory 300. The deep neural network accelerator 100 may be a system-on-chip device. The deep neural network accelerator 100 may act as a deep neural network (or artificial intelligence) computing device as an accelerator. The deep neural network accelerator 100 may exchange data with other external computing devices through an external interface. In addition, the deep neural network accelerator 100 may be connected to a non-volatile memory 310 and a volatile memory 320 through a bus. The processor 200 may be a control device that controls the system of the electronic device 1000 and executes a computation of a program. The processor 200 may be a general-purpose computing device and may be less efficient in performing parallel simple computations that are widely used in deep learning. Accordingly, the deep neural network accelerator 100 may perform a computation in deep learning inference and learning tasks at high efficiency. The processor 200 may exchange data with other external computing devices through an external interface. In addition, the processor 200 may be connected to each of the non-volatile memory 310 and the volatile memory 320 through a bus. The memory 300 may be a memory (off-chip memory) disposed outside a chip of the deep neural network accelerator 100. The memory 300 may include the non-volatile memory 310 and the volatile memory 320. The non-volatile memory 310 may be a memory that continuously maintains stored information therein even when power is not supplied thereto. For example, the non-volatile memory 310 may include at least one of ROM (Read-Only Memory), PROM (Programmable Read-Only Memory), EAROM (Erasable Alterable ROM), EPROM (Erasable Programmable Read-Only Memory), EEPROM (Electrically Erasable Programmable Read-Only Memory) (e.g., NAND Flash memory, NOR Flash memory), UVEPROM (Ultra-Violet Erasable Programmable Read-Only Memory), FeRAM (Ferroelectric Random Access Memory), MRAM (Magnetoresistive Random Access Memory), PRAM (Phase-change Random Access Memory), SONOS (silicon-oxide-nitride-oxide-silicon), RRAM (Resistive Random Access Memory), NRAM (Nanotube Random Access Memory), a magnetic computer memory device (e.g., a hard disk, a diskette drive, a magnetic tape), an optical disk drive, and a 3D crosspoint memory (3D XPoint memory), etc. However, the present disclosure is not limited thereto. Unlike the nonvolatile memory 310, the volatile memory 320 may be a memory that continuously needs to receive the power to maintain stored information therein. For example, the volatile memory 320 may include at least one of a dynamic random access memory (DRAM), a static random access memory (SRAM), a synchronous dynamic random access memory (SDRAM), and a double data rate SDRAM (DDR SDRAM). However, the present disclosure is not limited thereto. The bus may include, for example, at least one of Parallel Advanced Technology Attachment (PATA), Small Computer System Interface (SCSI), Serial Attached SCSI (SAS), Serial Advanced Technology Attachment (SATA), and PCI Express (PCIe). However, the present disclosure is not limited thereto. For example, the bus may be at least one of a single data rate (SDR), a double data rate (DDR), a quad data rate (QDR), an extreme data rate (XDR) (Octal Data Rate). However, the present disclosure is not limited thereto.

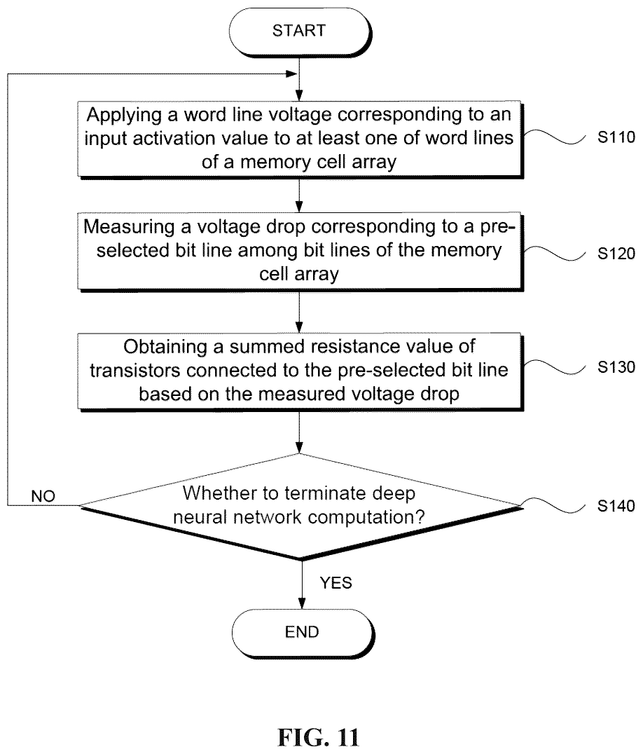

FIG. 11 is a flowchart illustrating a method for operating a deep neural network accelerator according to an embodiment of the present disclosure. Contents overlapping the contents as described above with reference to FIGS. 1 to 10 will be omitted. For convenience of description, FIG. 11 will be described with reference to FIGS. 1, 2, and 10.

Referring to FIG. 11, the method for operating the deep neural network accelerator performing the deep neural network computation of FIG. 7 may include operations S110 to S140. In an embodiment of the present disclosure, the operations S110 to S140 may be performed by the electronic device 1000, the processor 200 of the electronic device 1000, the deep neural network accelerator 100, or the control logic 150 of the deep neural network accelerator 100. The method for operating the deep neural network accelerator performing the deep neural network computation according to an embodiment of the present disclosure is not limited to that illustrated in FIG. 11, and any one of the operations as illustrated in FIG. 11 may be omitted, or may further include an operation as not illustrated in FIG. 11.

In operation S110, the deep neural network accelerator 100 may apply a word line voltage corresponding to the input activation value to at least one of the word lines of the memory cell array 110. The word line voltage may be generated through the voltage generator 140 and may be applied to the memory cell through the row driver 120.

In operation S120, the deep neural network accelerator 100 may measure a voltage drop corresponding to a pre-selected bit line among the bit lines of the memory cell array 110. The pre-selected bit line BL may be defined as one string. In an embodiment of the present disclosure, the deep neural network accelerator 100 may measure a voltage drop of all transistors of the pre-selected bit line. However, the present disclosure is not limited thereto. For example, the deep neural network accelerator 100 may measure a voltage drop of some of the transistors of the pre-selected bit line.

In operation S130, the deep neural network accelerator 100 may obtain a summed resistance value of the transistors connected to the pre-selected bit line based on the measured voltage drop. For example, the control logic 150 may calculate the summed resistance value resulting from the transistors based on the voltage drop and the drain current. However, the present disclosure is not limited thereto. The deep neural network accelerator 100 may transmit the measured voltage drop to the processor 200 through the bus. The processor 200 may calculate the summed resistance value resulting from the transistors based on the measured voltage drop and the drain current.

In an embodiment of the present disclosure, when the process of obtaining the summed resistance value of the pre-selected bit line is terminated, the procedure may move to operation S120 to measure a voltage drop corresponding to a next selected bit line, and perform the operation S130 again.

In operation S140, the deep neural network accelerator 100 and/or the processor 200 may determine whether to terminate the deep neural network computation. For example, the deep neural network accelerator 100 and/or the processor 200 may determine whether the computation on all layers of the deep neural network has ended. Based on determining that the calculation on all layers of the deep neural network has been completed, the procedure may be terminated. Based on determining that the calculation on all layers of the deep neural network has not been completed, the procedure moves to the operation S110.

In a first aspect of the present disclosure, a deep neural network accelerator may be provided. The deep neural network accelerator may include a memory cell array including memory cells arranged along word lines and bit lines, wherein at least one of the memory cells includes a first transistor programmed such that a threshold voltage thereof is shifted by a shift voltage corresponding to a weight value. The deep neural network accelerator may include a row driver configured to apply a word line voltage corresponding to an input activation value to the word lines corresponding to the first transistor. The deep neural network accelerator may include a column driver configured to measure a voltage drop caused by memory cells corresponding to a first bit line among the bit lines. In one embodiment of the deep neural network accelerator of the present disclosure, a gate-source voltage of the first transistor may be a voltage of a sub-threshold region. According to an embodiment of the present disclosure, using the gate-source voltage of the sub-threshold region may allow the multiplication between the input activation value and the weight value to be easily implemented using the memory cell array structure.

In one embodiment of the deep neural network accelerator of the present disclosure, a drain-source resistance value of the first transistor may correspond to a multiplication value between the input activation value and the weight value.

In one embodiment of the deep neural network accelerator of the present disclosure, the measured voltage drop may correspond to a value obtained by cumulatively summing multiplication values between the input activation values and the weight values of the memory cells corresponding to the first bit line.

In one embodiment of the deep neural network accelerator of the present disclosure, the first transistor may be manufactured through at least one of: a first process of implanting impurities into a channel forming area; a second process of adjusting a protective layer between the channel area and a gate insulating film; or a third process of omitting a process of forming the protective layer. In one embodiment of the deep neural network accelerator of the present disclosure, the sub-threshold region may be widened through at least one of the first to third processes.

In one embodiment of the deep neural network accelerator of the present disclosure, each of the memory cells may further include a bypass resistor element connected to and disposed between a drain terminal and a source terminal of the first transistor.

In one embodiment of the deep neural network accelerator of the present disclosure, each of the word lines may correspond to one of nodes of an input layer of the deep neural network. In one embodiment of the deep neural network accelerator of the present disclosure, each of the bit lines may correspond to one of nodes of an output layer of the deep neural network.

In one embodiment of the deep neural network accelerator of the present disclosure, the gate-source voltage may be a value obtained by applying a negative offset to a reference voltage, wherein the negative offset is a sum of the word line voltage and the shift voltage.

In one embodiment of the deep neural network accelerator of the present disclosure, each of the memory cells may include a NAND flash memory cell.

In one embodiment of the deep neural network accelerator of the present disclosure, at least one of the memory cells may include a second transistor. In one embodiment of the deep neural network accelerator of the present disclosure, the row driver may be configured to apply an on-state voltage to the word lines corresponding to the second transistor.

In a second aspect of the present disclosure, a method for operating a deep neural network accelerator performing a deep neural network computation may be provided. The method may include applying a word line voltage corresponding to an input activation value to at least one of word lines of a memory cell array. The method may include measuring a voltage drop corresponding to a pre-selected bit line among bit lines of the memory cell array. The method may include obtaining a summed resistance value of transistors connected to the pre-selected bit line based on the measured voltage drop. In the method, at least one of the transistors may be programmed such that a threshold voltage thereof is shifted by a shift voltage corresponding to a weight value. In an embodiment of the method, a gate-source voltage of each of the programmed at least one transistor may be a voltage of a sub-threshold region. According to an embodiment of the present disclosure, measuring the summed resistance value may allow the matrix computation of the deep neural network to be performed without an accumulator.

In a third aspect of the present disclosure, an electronic device may be provided. The electronic device may include a deep neural network accelerator configured to perform a matrix computation of a deep neural network. The electronic device may include a memory configured to store therein at least partial data of the deep neural network. The electronic device may include a processor configured to control the deep neural network accelerator and the memory. The deep neural network accelerator may include a memory cell array including memory cells arranged along word lines and bit lines, wherein at least one of the memory cells includes a first transistor programmed such that a threshold voltage thereof is shifted by a shift voltage corresponding to a weight value of the deep neural network. The deep neural network accelerator may include a row driver configured to apply a word line voltage corresponding to an input activation value of the deep neural network to the word lines corresponding to the first transistor. The deep neural network accelerator may include a column driver configured to measure a voltage drop caused by memory cells corresponding to a first bit line among the bit lines. In one embodiment of the electronic device, a gate-source voltage of the first transistor may be a voltage of a sub-threshold region.

In an embodiment of the present disclosure, the matrix computation may be an inference computation.

The method according to an embodiment of the present disclosure may be implemented in the form of a program instruction that may be performed through various computer means and thus may be recorded in a computer-readable medium. The computer-readable medium may include program instructions, data files, data structures, and the like alone or in combination with each other. The program instructions recorded in the medium may be specially designed and configured for the purpose of the present disclosure, or may be known and available to those skilled in the computer software. Examples of the computer readable recording medium include magnetic media such as a hard disk, a floppy disk, and a magnetic tape, optical media such as a CD-ROM and a DVD, magneto-optical media such as a floptical disk, and a hardware device specially configured to store therein and execute the program instructions such as a ROM, a RAM, and a flash memory. Examples of the program instructions include not only machine language codes such as those generated by a compiler, but also high-level language codes that may be executed by a computer using an interpreter or the like.

Some embodiments of the present disclosure may also be implemented in the form of a recording medium including instructions executable by a computer, such as a program module executed by a computer. The computer-readable medium may be any available medium that may be accessed by a computer, and includes both volatile and non-volatile media, removable and non-removable media. In addition, the computer-readable medium may include both a computer storage medium and a communication medium. The computer storage medium includes both volatile and non-volatile, removable and non-removable media implemented in any method or technology for the storage of information such as computer readable instructions, data structures, program modules, or other data. The communication media typically include computer-readable instructions, data structures, program modules, or other data of modulated data signals such as carrier waves, or other transmission mechanisms, and include any information delivery media. Some embodiments of the present disclosure may also be embodied as a computer program or a computer program product comprising instructions executable by a computer, such as a computer program executed by a computer.

In an embodiment of the present disclosure, a device-readable storage medium may be provided in the form of a non-transitory storage medium. In this regard, “non-transitory storage medium” is a tangible device, and only means that it does not include a signal (e.g., electromagnetic wave), and this term does not distinguish a case in which data is semi-permanently stored in a storage medium and a case in which data is temporarily stored therein from each other. For example, the “non-transitory storage medium” may include a buffer in which data is temporarily stored.

According to an embodiment of the present disclosure, the method according to various embodiments disclosed in the present disclosure may be provided while being included in a computer program product. The computer program products may be traded between sellers and buyers as commodities. The computer program product may be distributed in the form of a storage medium (e.g., a compact disc read only memory (CD-ROM)) readable by a device, or may be distributed (e.g., downloaded or uploaded) directly or online through an application store or between two user devices (e.g., smartphones). In the case of online distribution, at least a portion of the computer program product (e.g., a downloadable app) may be at least temporarily stored in a storage medium readable by a device such as a server of a manufacturer, a server of an application store, or a relay server, or may be temporarily generated thereby.

Although the embodiments of the present disclosure have been described in detail above, the scope of the present disclosure is not limited thereto, and various modifications and improvements made by those skilled in the art using the basic concept of the present disclosure as defined in the following claims also belong to the scope of the present disclosure.

What is claimed is:

1. A deep neural network accelerator comprising:
a memory cell array including memory cells arranged along word lines and bit lines, wherein at least one of the memory cells includes a first transistor programmed such that a threshold voltage thereof is shifted by a shift voltage corresponding to a weight value;
a row driver configured to apply a word line voltage corresponding to an input activation value to the word lines corresponding to the first transistor; and
a column driver configured to measure a voltage drop caused by memory cells corresponding to a first bit line among the bit lines,
wherein a gate-source voltage of the first transistor is a voltage of a sub-threshold region.

2. The deep neural network accelerator of claim 1, wherein a drain-source resistance value of the first transistor corresponds to a multiplication value between the input activation value and the weight value.

3. The deep neural network accelerator of claim 1, wherein the measured voltage drop corresponds to a value obtained by cumulatively summing multiplication values between the input activation values and the weight values of the memory cells corresponding to the first bit line.

4. The deep neural network accelerator of claim 1, wherein the first transistor is manufactured through at least one of:
a first process of implanting impurities into a channel forming area;
a second process of adjusting a protective layer between the channel area and a gate insulating film; or
a third process of omitting a process of forming the protective layer,
wherein the sub-threshold region is widened through at least one of the first to third processes.

5. The deep neural network accelerator of claim 1, wherein each of the memory cells further includes a bypass resistor element connected to and disposed between a drain terminal and a source terminal of the first transistor.

6. The deep neural network accelerator of claim 1, wherein each of the word lines corresponds to one of nodes of an input layer of the deep neural network,
wherein each of the bit lines corresponds to one of nodes of an output layer of the deep neural network.

7. The deep neural network accelerator of claim 1, wherein the gate-source voltage is a value obtained by applying a negative offset to a reference voltage, wherein the negative offset is a sum of the word line voltage and the shift voltage.

8. The deep neural network accelerator of claim 1, wherein each of the memory cells includes a NAND flash memory cell.

9. The deep neural network accelerator of claim 1, wherein at least one of the memory cells includes a second transistor,
wherein the row driver is configured to apply an on-state voltage to the word lines corresponding to the second transistor.

10. A method for operating a deep neural network accelerator performing a deep neural network computation, the method comprising:
applying a word line voltage corresponding to an input activation value to at least one of word lines of a memory cell array;
measuring a voltage drop corresponding to a pre-selected bit line among bit lines of the memory cell array; and
obtaining a summed resistance value of transistors connected to the pre-selected bit line based on the measured voltage drop,
wherein at least one of the transistors is programmed such that a threshold voltage thereof is shifted by a shift voltage corresponding to a weight value,
wherein a gate-source voltage of each of the programmed at least one transistor is a voltage of a sub-threshold region.

11. An electronic device comprising:
a deep neural network accelerator configured to perform a matrix computation of a deep neural network;
a memory configured to store therein at least partial data of the deep neural network; and
a processor configured to control the deep neural network accelerator and the memory,
wherein the deep neural network accelerator includes:
a memory cell array including memory cells arranged along word lines and bit lines, wherein at least one of the memory cells includes a first transistor programmed such that a threshold voltage thereof is shifted by a shift voltage corresponding to a weight value of the deep neural network;
a row driver configured to apply a word line voltage corresponding to an input activation value of the deep neural network to the word lines corresponding to the first transistor; and
a column driver configured to measure a voltage drop caused by memory cells corresponding to a first bit line among the bit lines,
wherein a gate-source voltage of the first transistor is a voltage of a sub-threshold region.

12. The electronic device of claim 11, wherein a drain-source resistance value of the first transistor corresponds to a multiplication value between the input activation value and the weight value.

13. The electronic device of claim 11, wherein the measured voltage drop corresponds to a value obtained by cumulatively summing multiplication values between the input activation values and the weight values of the memory cells corresponding to the first bit line.

14. The electronic device of claim 11, wherein the first transistor is manufactured through at least one of:
a first process of implanting impurities into a channel forming area;
a second process of adjusting a protective layer between the channel area and a gate insulating film; or
a third process of omitting a process of forming the protective layer,
wherein the sub-threshold region is widened through at least one of the first to third processes.

15. The electronic device of claim 11, wherein each of the memory cells further includes a bypass resistor element connected to and disposed between a drain terminal and a source terminal of the first transistor.

16. The electronic device of claim 11, wherein each of the word lines corresponds to one of nodes of an input layer of the deep neural network,
wherein each of the bit lines corresponds to one of nodes of an output layer of the deep neural network.

17. The electronic device of claim 11, wherein the gate-source voltage is a value obtained by applying a negative offset to a reference voltage, wherein the negative offset is a sum of the word line voltage and the shift voltage.

18. The electronic device of claim 11, wherein each of the memory cells includes a NAND flash memory cell.

19. The electronic device of claim 11, wherein at least one of the memory cells includes a second transistor,
wherein the row driver is configured to apply an on-state voltage to the word lines corresponding to the second transistor.

20. The electronic device of claim 11, wherein the matrix computation is an inference computation.
